(19) United States
(12) Patent Application Publication
(10) Pub. No.: US 2025/0004013 A1
(43) Pub. Date: Jan. 2, 2025

(54) PROBE CARD STRUCTURE

(71) Applicant: teCat Technologies (Suzhou) Limited, SUZHOU CITY (CN)

(72) Inventor: CHOON LEONG LOU, SINGAPORE (SG)

(21) Appl. No.: 18/522,398

(22) Filed: Nov. 29, 2023

(30) Foreign Application Priority Data
Jun. 27, 2023 (CN) 202310765529.1

(51) Int. Cl. G01R 1/073

(52) U.S. Cl. CPC G01R 1/07321; G01R 1/07357

(57) ABSTRACT

A probe card structure includes an upper guide plate set, a lower guide plate set, a first probe set, a second probe set, and a stiffener. The lower guide plate set includes a first lower guide plate and a second guide plate. The first probe set includes a plurality of first probes each having a first contact end passing through an upper guide plate hole and a second contact end passing through a lower guide plate hole. The second probe set includes a plurality of second probes each having a different length from that of the first probe, and having a third contact end passing through the upper guide plate hole and a fourth contact end passing through the lower guide plate hole. A position of the second lower guide plate determines a length of the fourth contact end projecting from the lower guide plate set.

### CROSS-REFERENCE TO RELATED PATENT APPLICATION

This application claims the benefit of priority to China Patent Application No. 202310765529.1, filed on Jun. 27, 2023, in the People's Republic of China. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a probe card structure, and more particularly to a probe card structure for testing device under test (DUT) having different heights.

### BACKGROUND OF THE DISCLOSURE

When the semiconductor test is conducted, a probe card is used to be in contact with the pads or bumps on the DUT, and the electrical signals detected are analyzed to obtain test results of the DUT. In the Chip-on-Wafer-on-Substrate (CoWoS) packaging process, different chips are first interconnected together through a wafer-level silicon interposer (Si interposer) to form a Chip-on-Wafer (CoW) wafer, which is then attached to a substrate.

In the conventional technology, since the DUT (or called objects to be tested) are located at the same level on the same substrate, the test can be smoothly conducted as long as the tips of the probes are controlled to at the same level. However, as shown in FIG. 1, when a silicon interposer S1 is provided with objects to be tested T (e.g., chips) having different heights, and a probe card test is conducted after the CoWoS packaging process, the heights of the objects to be tested T may be different from each other, resulting in that probes P not being able to be in uniform contact of the corresponding pads or bumps of the objects to be tested T, so that accuracy of the test is affected.

Therefore, how to improve the test capabilities of the probe card through structural design improvements so as to test objects to be tested having different heights, to overcome the above issues has become one of the important issues to be addressed in the related field.

SUMMARY OF THE DISCLOSURE

In response to the above-referenced technical inadequacies, the present disclosure provides a probe card structure.

In order to solve the above-mentioned problems, one of the technical aspects adopted by the present disclosure is to provide a probe card structure, which includes an upper guide plate set, a lower guide plate set, a first probe set, a second probe set, and at least one stiffener. The upper guide plate set includes at least a first upper guide plate. The lower guide plate set is arranged parallel to the upper guide plate set and includes at least a first lower guide plate and a second lower guide plate. Each of the first lower guide plate and the second lower guide plate has a plurality of lower guide plate holes. The first probe set includes a plurality of first probes. Each of the plurality of first probes has a first contact end and a second contact end, the first contact ends correspondingly pass through the plurality of upper guide plate holes, and the second contact ends correspondingly pass through the plurality of lower guide plate holes. The second probe set includes a plurality of second probes which have different lengths from those of the plurality of first probes. Each of the plurality of second probes has a third contact end and a fourth contact end, the third contact ends correspondingly pass through the plurality of upper guide plate holes, and the fourth contact ends correspondingly pass through the plurality of lower guide plate holes. The length of each of the plurality of second probes is greater than the length of each of the plurality of first probes. The at least one stiffener is disposed between the first lower guide plate and the second lower guide plate. The plurality of first probes and the plurality of second probes correspondingly pass through the first upper guide plate, and the plurality of first probes and the plurality of second probes correspondingly pass through at least one of the first lower guide plate and the second lower guide plate. A position of the first lower guide plate determines lengths of the second contact ends projecting from the lower guide plate set, and a position of the second lower guide plate determines lengths of the fourth contact ends projecting from the lower guide plate set. The first contact ends and the third contact ends are coplanar, and the second contact ends and the fourth contact ends are not coplanar.

Therefore, in the probe card structure and the method of manufacturing the same provided by the present disclosure, by virtue of “the upper guide plate set including at least the first upper guide plate, and the first upper guide plate having the plurality of upper guide plate holes; the lower guide plate set being arranged parallel to the upper guide plate set and including at least the first lower guide plate and the second lower guide plate, each of the first lower guide plate and the second lower guide plate having the plurality of lower guide plate holes,” “the first probe set including the plurality of first probes, each of the plurality of first probes having the first contact end and the second contact end, the first contact ends correspondingly passing through the plurality of upper guide plate holes, and the second contact ends correspondingly passing through the plurality of lower guide plate holes; the second probe set including the plurality of second probes which have different lengths from those of the plurality of first probes, each of the plurality of second probes having the third contact end and the fourth contact end, the third contact ends correspondingly passing through the plurality of upper guide plate holes, and the fourth contact ends correspondingly passing through the plurality of lower guide plate holes; the length of each of the plurality of second probes being greater than the length of each of the plurality of first probes,” “the least one stiffener being disposed between the first lower guide plate and the second lower guide plate,” “the plurality of first probes and the plurality of second probes correspondingly passing through the first upper guide plate, and the plurality of first probes and the plurality of second probes correspondingly passing through at least one of the first lower guide plate and the second lower guide plate,” “the position of the first lower guide plate determining the lengths of the second contact ends projecting from the lower guide plate set, and the position of the second lower guide plate determining the lengths of the fourth contact ends projecting from the lower guide plate set,” and “the first contact ends and the third contact ends being coplanar, and the second contact ends and the fourth contact ends being not coplanar,” the probes can be in uniform contact with the corresponding pads or bumps on the objects to be tested, so that a test capability of the probe card can be improved.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view showing a technical problem of the conventional technology;

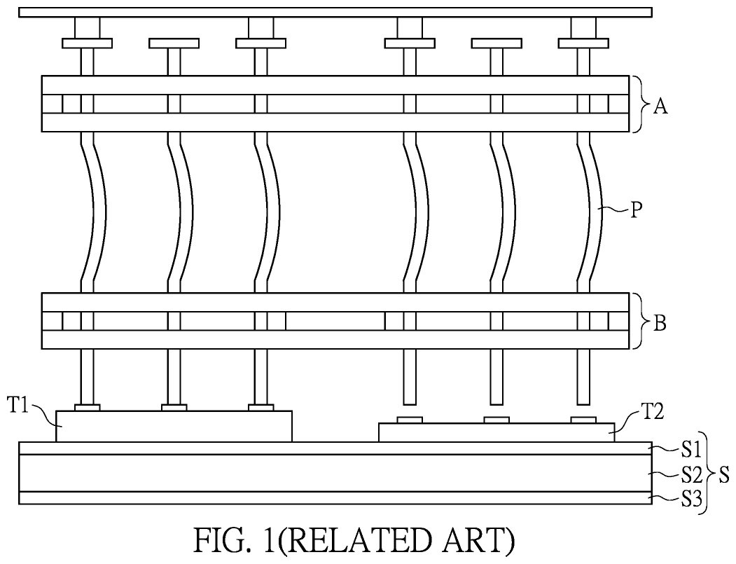

FIG. 2A is a schematic side view according to a first embodiment of the present disclosure;

FIG. 2B is a schematic side view according to another embodiment of the present disclosure;

FIG. 3A is a schematic side view according to a second embodiment of the present disclosure;

FIG. 3B is a schematic side view according to yet another embodiment of the present disclosure;

FIG. 4 is a schematic side view according to a third embodiment of the present disclosure;

FIG. 5 is a schematic side view according to a fourth embodiment of the present disclosure;

FIG. 6 is a schematic side view according to a fifth embodiment of the present disclosure;

FIG. 7 is a schematic side view according to a sixth embodiment of the present disclosure; and

FIG. 8 is a schematic side view according to a seventh embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

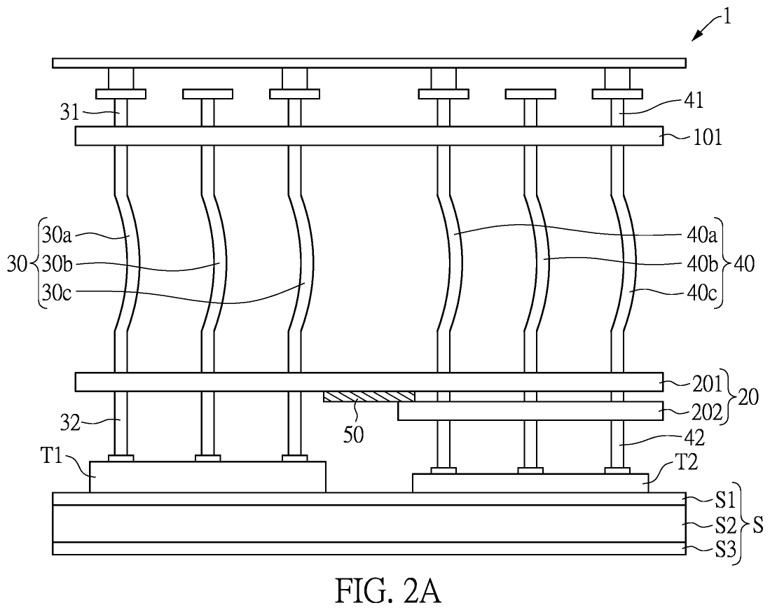

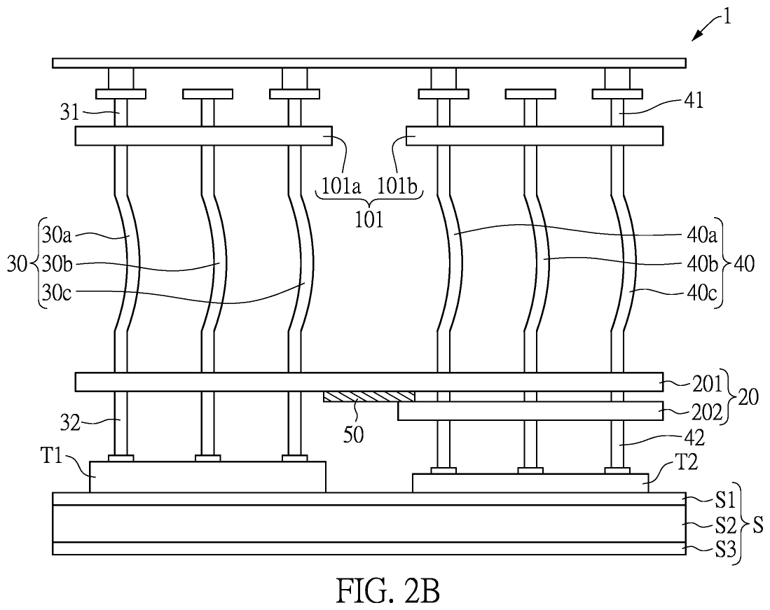

Referring to FIG. 2, a first embodiment of the present disclosure provides a probe card structure 1 configured for testing electrical properties of a first object to be test T1 and a second object to be tested T2. The probe card structure 1 includes an upper guide plate set 10, a lower guide plate set 20, a first probe set 30, a second probe set 40, and at least one stiffener 50. The upper guide plate set 10 includes at least a first upper guide plate 101, and the first upper guide plate 101 has a plurality of upper guide plate holes (not shown in the figures). The lower guide plate set 20 includes at least a first lower guide plate 201 and a second lower guide plate 202, and each of the first lower guide plate 201 and the second lower guide plate 202 has a plurality of lower guide holes (not shown in the figures). The first upper guide plate 101 and the lower guide plate set 20 are arranged parallel to each other, that is, the first upper guide plate 101, the first lower guide plate 201, and the second lower guide plate are parallel to each other.

The first probe set 30 includes a plurality of first probes 30a, 30b, 30c, each having a first contact end 31 and a second contact end 32. The first contact ends 31 correspondingly pass through the upper guide plate holes, and the second contact ends 32 correspondingly pass through the lower guide plate holes. Accordingly, the first contact ends 31 correspondingly project from the upper guide plate holes of the first upper guide plate 101 and are connected to electrically conductive contacts of a space transformer or a main circuit board, and the second contact ends 32 correspondingly project from the lower guide plate holes of the lower guide plate set 20 to contact the first object to be tested T1. In one particular embodiment, a length of each of the plurality of first probes 30a, 30b, 30c is the same.

The second probe set 40 includes a plurality of second probes 40a, 40b, 40c, each having a third contact end 41 and a fourth contact end 42. The third contact ends 41 correspondingly pass through the upper guide plate holes, and the fourth contact ends 42 correspondingly pass through the lower guide plate holes. Accordingly, the third contact ends 41 correspondingly project from the upper guide plate holes of the first upper guide plate 101 and are connected to electrically conductive contacts of the space transformer or the main circuit board, and the fourth contact ends 42 correspondingly project from the lower guide plate holes of the lower guide plate set 20 to contact the second object to be tested T2. In one particular embodiment, a length of each of the plurality of second probes 40a, 40b, 40c is the same. It should be noted that the length of each of the plurality of second probes 40a, 40b, 40c is different form the length of each of the plurality of first probes 30a, 30b, 30c. In one particular embodiment, the first contact ends 31 of the plurality of first probes 30a, 30b, 30c and the third contact ends 41 of the second probes 40a, 40b, 40c are coplanar at the electrically conductive contacts of the space transformer or the main circuit board. In one particular embodiment, as shown in FIG. 2B, the first upper guide plate 101 has a first section 101a and a second section 101b that are separated from each other. The first probe set 30 passes through the first section 101a, and the second probe set 40 passes through second section 101b.

In one particular embodiment of the present disclosure, at least one of the first upper guide plate 101 and the first lower guide plate 201 is integrally formed. That is, the first probe set 30 and the second probe set 40 share at least one of the first upper guide plate 101 and the first lower guide plate 201.

Further, the plurality of first probes 30a, 30b, 30c and the plurality of second probes 40a, 40b, 40c are vertical probes, such as vertical pogo pins. However, a type of probe applied in the present disclosure is not limited as long as the vertical probes can be mounted on a probe card to test the objects to be tested (i.e., the first object to be tested T1 and the second object to be tested T2). Specifically, the plurality of first probes 30a, 30b, 30c and the plurality of second probes 40a, 40b, 40c each can be made of metal with a high conductivity and elasticity, such as copper, palladium, silver, gold, and platinum. In a preferable embodiment, the plurality of first probes 30a, 30b, 30c and the plurality of second probes 40a, 40b, 40c each can further include an insulation cover layer.

The first probe set 30 and the second probe set 40 may pass through different numbers of lower guide plates. For example, the plurality of first probes 30a, 30b, 30c pass only through the first lower guide plate 201, while the plurality of second probes 40a, 40b, 40c correspondingly pass through the first lower guide plate 201 and the second lower guide plate 202. That is, when viewed from a side of the probe card structure, a length of the first lower guide plate 201 and a length of the second lower guide plate 202 are different. In certain embodiments, when viewed from the side of the probe card structure, a thickness of the first lower guide plate 201 and a thickness of the second lower guide plate 202 may be different. In order to provide the first probe set 30 and the second probe set 40 with a sufficient stress to bear a force of probing a device under test, the probe card structure of the present disclosure applying the vertical probes includes the stiffener 50 (e.g., a spacer). Typically, the stiffener is made of a reinforced material, such as iron and stainless steel. In an application of the present disclosure, the stiffener 50 can be disposed between the first lower guide plate 201 and the second lower guide plate 202 to fix a distance between the first lower guide plate 201 and the second lower guide plate 202, thereby providing the sufficient stress.

In other words, the stiffener 50 can be used to connect the first lower guide plate 201 and the second lower guide plate 202 and maintain a predetermined distance between the first lower guide plate 201 and the second lower guide plate 202 in a longitudinal direction. It should be noted that a number and a position of the stiffener 50 can be adjusted according to practical requirements as long as the force generated when the probes are in contact with the objects to be tested with different heights (i.e., the first object to be tested T1 and the second object to be tested T2) can be supported by the stiffener 50. In the probe card structure 1 of the present disclosure, multiple stiffeners 50 may be of different sizes.

In one particular embodiment, the first probe set 30 passes through the first lower guide plate 201, and the second probe set 40 correspondingly passes through the first lower guide plate 201 and the second lower guide plate 202. In other words, the plurality of second probes 40a, 40b, 40c correspondingly pass through the first lower guide plate 201 and the second lower guide plate 202 in a manner that the plurality of first probes 30a, 30b, 30c and the plurality of second probes 40a, 40b, 40c each are exposed from the lower guide plate set 20 by the same length. That is, lengths of the fourth contact ends projecting from the lower guide plate set 20 are determined according to a position of the second lower guide plate 202. In the present embodiment, a distance between the second lower guide plate 202 and the first upper guide plate 101 is greater than a distance between the first lower guide plate 201 and the first upper guide plate 101, and the length of the second lower guide plate 202 is greater than the length of the first lower guide plate 201.

In order to ensure that tips of the first probe set 30 and tips of the second probe set 40 have a very similar balance contact force, in addition to adjusting lengths of the second contact ends 32 and the lengths of the fourth contact ends 42 projecting from the lower guide plate set 20, the first probe set 30 and the second probe set 40 may adopt probes having different tip thicknesses. In other words, the lengths of the fourth contact ends projecting from the lower guide plate set 20 and the thicknesses of the second probe set 40 contribute to an elasticity of the second probe set 40 and a contact force to the device under test.

During an actual test, the first object to be tested T1 and the second object to be tested T2 are disposed on a substrate S, and the substrate S can include a silicon interposer S1, a package substrate S2, and a circuit board S3 in sequence. When the first object to be tested T1 and the second object to be tested T2 disposed on a same substrate S have different heights, for the second object to be tested T2 having a lower height, the lengths of the plurality of second probes 40a, 40b, 40c can be increased so as to be in contact with the second object to be tested T2. Further, the lengths of the fourth contact ends 42 of the plurality of second probes 40a, 40b, 40c projecting from the second lower guide plate 202 are determined through adjusting the second lower guide plate 202. Therefore, the probe card structure 1 of the present disclosure can be used to test the first object to be tested T1 and the second object to be tested T2 having different heights at the same time, thereby particularly applicable for a chip-on-wafer-on-substrate packaging process.

### Second Embodiment

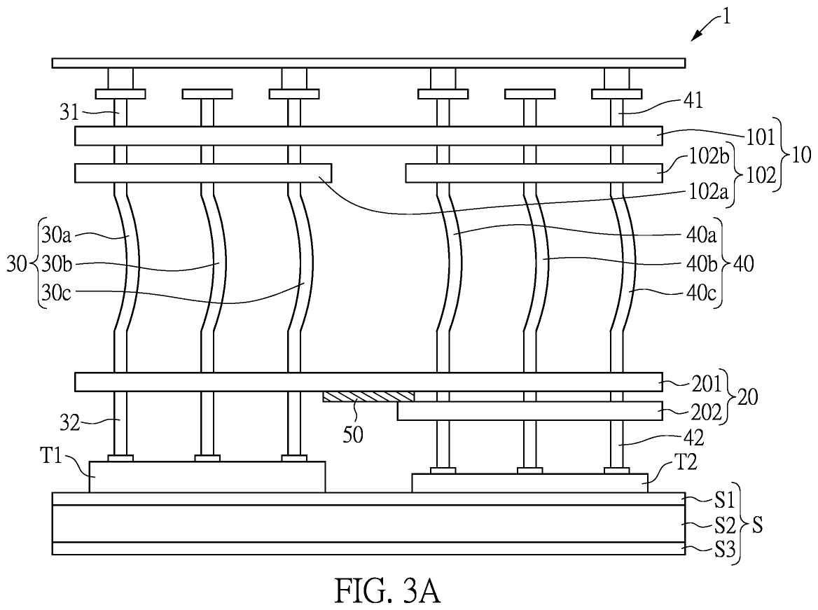

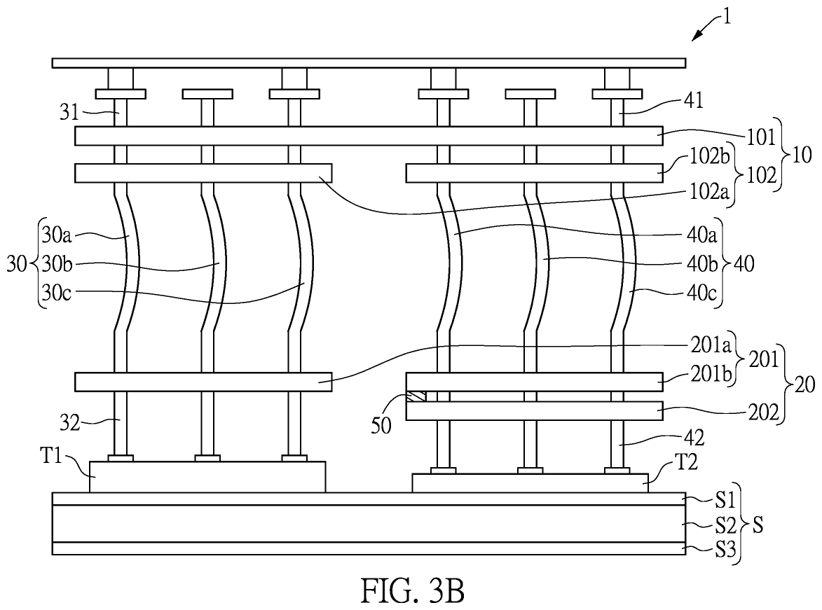

Referring to FIG. 3A, which a second embodiment of the present disclosure is shown, the present embodiment is substantially the same as the first embodiment, and the main difference is described as follows. In the second embodiment of the present disclosure, the upper guide plate set 10 further includes a second upper guide plate 102. The second upper guide plate 102 and the first upper guide plate 101 are arranged parallel to each other, and the second upper guide plate 102 has the plurality of upper guide plate holes corresponding to the plurality of upper guide plate holes of the first upper guide plate 101.

In one particular embodiment of the present disclosure, the first upper guide plate 101 is integrally formed, and the second upper guide plate 102 has a third section 102a and a fourth section 102b that are separated from each other. The first probe set 30 passes through the third section 102a, and the second probe set 40 passes through the fourth section 102b.

In another embodiment of the present disclosure, as shown in FIG. 3B, the first upper guide plate is integrally formed, the second upper guide plate 102 has the third section 102a and the fourth section 102b that are separated from each other, and the first lower guide plate 201 can also have a fifth section 201a and a sixth section 201b that are separated from each other. The first probe set 30 correspondingly passes through the first upper guide plate 101, the third section 102a, and the fifth section 201b, and the second probe set 40 correspondingly passes through the upper guide plate 101, the fourth section 102b, the sixth section 201b, and the second lower guide plate 202.

### Third Embodiment

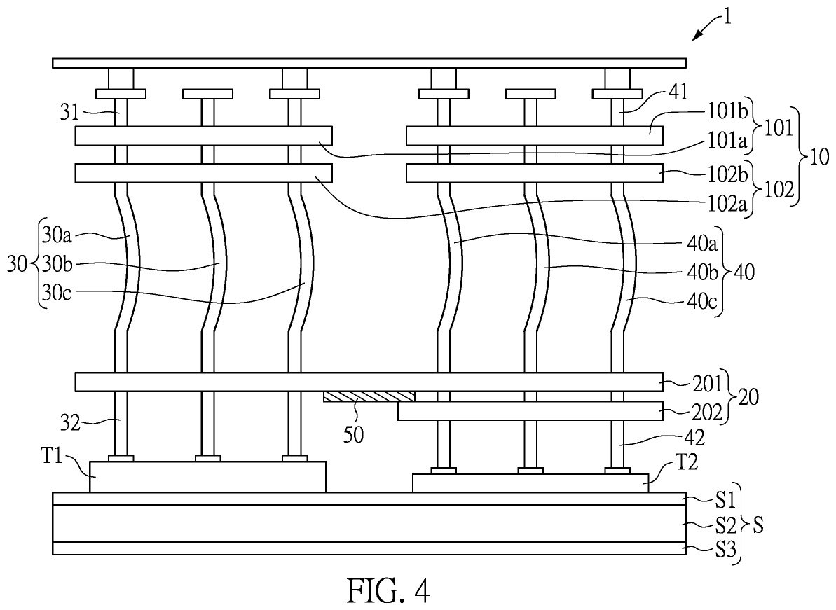

Referring to FIG. 4, which third embodiment of the present disclosure is shown, the present embodiment is substantially the same as the second embodiment, and the main difference is described as follows. In a probe card structure according to the third embodiment of the present disclosure, the first lower guide plate 201 is integrally formed, the first upper guide plate 101 has the first section 101a and the second section 101b that are separated from each other, and the second upper guide plate 102 has the third section 102a and the fourth section 102b that are separated from each other. The first probe set 30 correspondingly passes through the first section 101a, the third section 102a, and the first lower guide plate 201, and the second probe set 40 correspondingly passes through the second section 101b, the fourth section 102b, the first lower guide plate 201, and the second lower guide plate 202.

### Fourth Embodiment

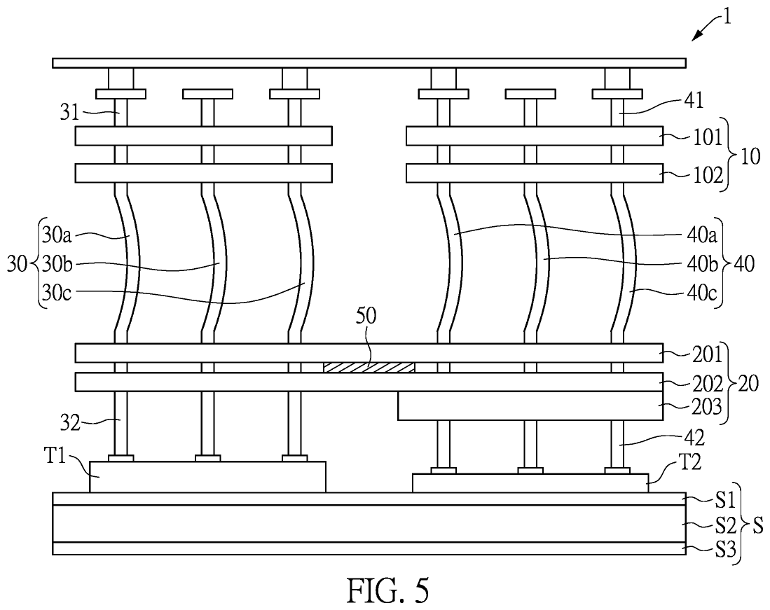

Referring to FIG. 5, which a fourth embodiment of the present disclosure is shown, the present embodiment is substantially the same as the third embodiment, and the main difference is described as follows. In a probe card structure according to the fourth embodiment of the present disclosure, the upper guide plate set 10 and the lower guide plate set 20 the probe card structure 1 each may include different numbers of guide plates. Specifically, the lower guide plate 20 further includes a third lower guide plate 203, and a thickness of the first lower guide plate 201 is different from a thickness of the third lower guide plate 203.

In one particular embodiment, a length of the third lower guide plate 203 is less than each of the length of the first lower guide plate 201 and the length of second lower guide plate 202. Further, the third lower guide 203 has the plurality of lower guide plate holes (not shown in the figures), and a distance between the third lower guide plate 203 and the first upper guide plate 101 is less than the distance between the first lower guide plate 201 and the first upper guide plate 101. In one particular embodiment, the first probe set 30 correspondingly passes through the lower guide plate holes of the first lower guide plate 201 and the second lower guide plate 202, and the second probe set 40 correspondingly passes through the lower guide plate holes of the first lower guide plate 201, the second lower guide plate 202, and the third lower guide plate 203.

In one particular embodiment of the present disclosure, the stiffener 50 may be not disposed between the second lower guide plate 202 and the third lower guide plate 203. Specifically, the probe card structure 1 is configured in a manner that the thickness of the third lower guide plate 203 is greater than each of the thickness of the first lower guide plate 201 and the thickness of the second lower guide plate 202, so as to compensate for a height difference caused by the absence of the stiffener 50. Accordingly, the stiffener 50 can be not provided between the second lower guide plate 202 and the third lower guide plate 203. Therefore, even if the stiffener 50 is not provided between the second lower guide plate 202 and the third lower guide plate 203, the length of the fourth contact end 42 projecting from the lower guide plate set 20 can be determined by the third lower guide plate 203 having the thicker thickness. In one particular embodiment, the first lower guide plate 201 can have the fifth section 201a and the sixth section 201b that are separated from each other, the first probe set 30 passes through the fifth section 201a, and the second probe set 40 passes through the sixth section 201b.

### Fifth Embodiment

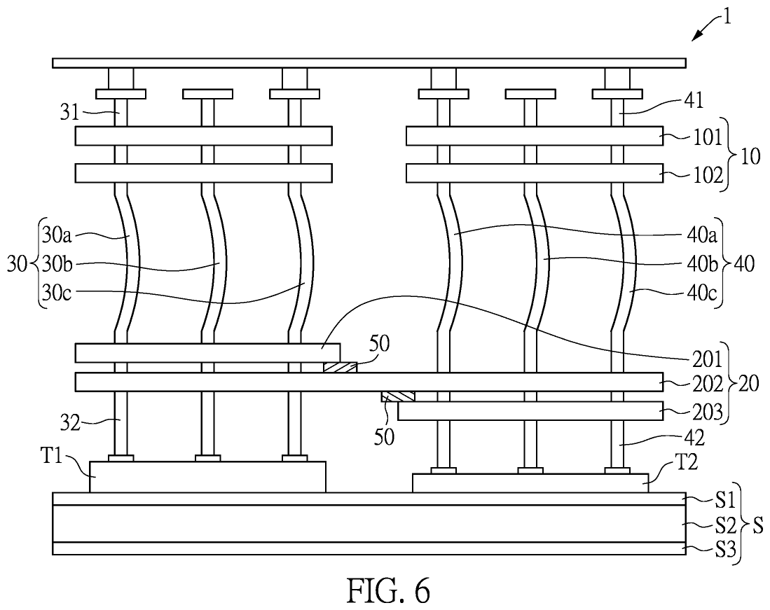

Referring to FIG. 6, which a fifth embodiment of the present disclosure is shown, the present embodiment is substantially the same as the fourth embodiment, and the main difference is described as follows. In a probe card structure of the fifth embodiment of the present disclosure, the first probe set 30 correspondingly passes through the lower guide plate holes of the first lower guide plate 201 and the second lower guide plate 202, and the second probe set 40 correspondingly passes through the lower guide plate holes of the second lower guide plate 202 and the third lower guide plate 203. In addition, the length of the first lower guide plate 201 is less than the length of the second lower guide plate 202, and the length of the third lower guide plate 203 is less than the length of the second lower guide plate 202.

In one particular embodiment, each of a size of the first lower guide plate 201 and a size of the third lower guide plate 203 is less than a size of the second lower guide plate 202. That is, when viewed from the side of the probe card structure, each of the length of the first lower guide plate 201 and the length of the third lower guide plate 203 is less than the length of the second lower guide plate 202. In the present embodiment, the second lower guide plate 202 have the longest length, such that manufacturing costs can be saved while the plurality of probes 40a, 40b, 40c are extended.

Further, a projection of the first lower guide plate 201 does not overlap with a projection of the third lower guide plate 203 in a longitudinal direction, such that the lengths correspondingly of the plurality of first probes 30a, 30b, 30c and the plurality of second probes 40a, 40b, 40c having different lengths projecting from the lower guide plate 20 can be determined. In other words, the plurality of first probes 30a, 30b, 30c correspondingly pass through the first lower guide plate 201 and the second lower guide plate 202, the plurality of second probes 40a, 40b, 40c correspondingly pass through the second lower guide plate 202 and the third lower guide plate 203. When the plurality of first probes 30a, 30b, 30c correspondingly pass through the first lower guide plate 201 and the second lower guide plate 202, a distance between the second lower guide plate 202 and the first object to be tested T1 is set as a first distance. When the plurality of second probes 40a, 40b, 40c correspondingly pass through the second lower guide plate 202 and the third lower guide plate 203, a distance between the third lower guide plate 203 and the second object to be tested T2 is set as a second distance. The first distance is substantially equal to the second distance.

### Sixth Embodiment

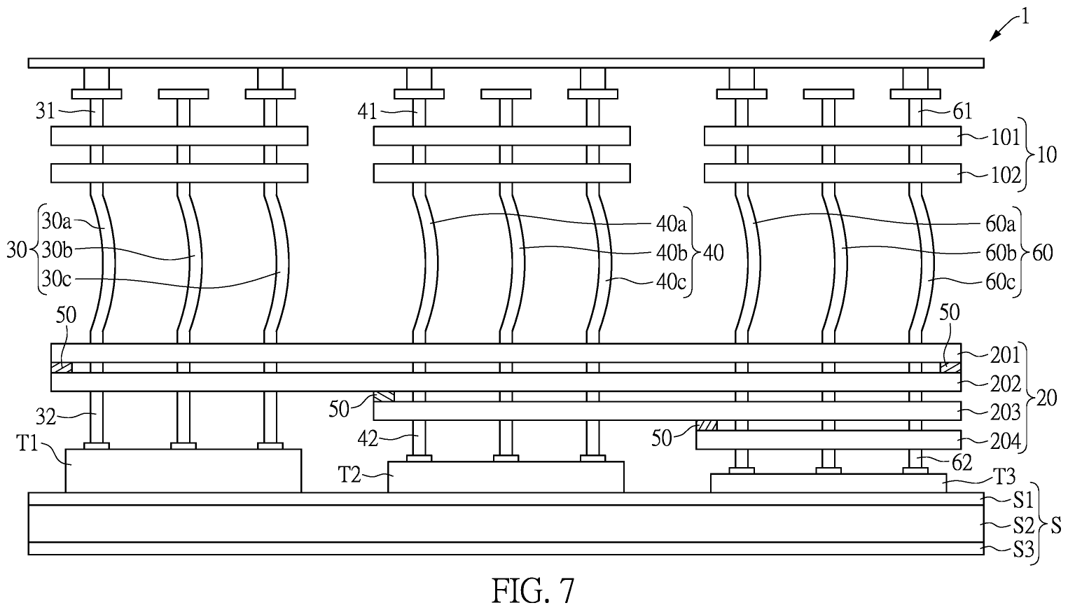

Referring to FIG. 7, which a sixth embodiment of the present disclosure is shown, the present embodiment is substantially the same as the fifth embodiment, and the main difference is described as follows. In the probe card structure of the sixth embodiment of the present disclosure, the probe card structure 1 can further include a third probe set 60. The third probe set 60 includes a plurality of third probes 60a, 60b, 60c each having a fifth contact end 61 and a sixth contact end 62. The fifth contact ends 61 correspondingly pass through the upper guide plate holes, and the sixth contact ends 62 correspondingly pass through the lower guide plate holes, so that the fifth contact ends 61 correspondingly project from the upper guide plate holes of the upper guide plate set 10 and are connected to the electrically conductive contacts of the space transformer or the main circuit board, and the sixth contact ends 62 correspondingly project from the lower guide plate holes of the lower guide plate set 20 and are in contact with the third object to be tested T3. In one particular embodiment, the first contact ends 31 of the plurality of first probes 30a, 30b, 30c, the third contact ends 41 of the plurality of second probes 40a, 40b, 40c, and the fifth contact ends 61 of the plurality of third probes 60a, 60b, 60c are coplanar at the electrically conductive contacts of the space transformer or the main circuit board. The second contact ends 32 of the plurality of first probes 30a, 30b, 30c, the fourth contact ends 42 of the plurality of second probes 40a, 40b, 40c, and the sixth contact ends 62 of the plurality of third probes 60a, 60b, 60c are not coplanar.

A length of each of the plurality of third probes 60a, 60b, 60c is different is different form the lengths of each of the plurality of first probes 30a, 30b, 30c and the plurality of second probes 40a, 40b, 40c, and the length of each of the plurality of first probes 30a, 30b, 30c is different from the length of each of plurality of second probes 40a, 40b, 40c. In one particular embodiment, the length of each of the plurality of third probes 60a, 60b, 60c is greater than the length of each of the plurality of second probes 40a, 40b, 40c, and the length of each of the plurality of second probes 40a, 40b, 40c is greater than the length of each of the plurality of first probes 30a, 30b, 30c. In order to adjust the lengths of the sixth contact ends 62 of the plurality of third probes 60a, 60b, 60c projecting from the lower guide plate set 20, the probe card structure 1 can further include a fourth lower guide plate 204, and the fourth lower guide plate 204 also has the plurality of lower guide plate holes. A size of the fourth lower guide plate 204 is different from the size of the first lower guide plate 201, the size of the second lower guide plate 202, or the size of the third lower guide plate 203. For example, the fourth guide plate 204 has a smallest size. A position of the fourth lower guide plate 204 determines the lengths of the sixth contact ends 62 projecting from the lower guide plate set 20. When viewed from the side of the probe card structure 1, a length of the fourth lower guide plate 204 is different from the length of the first lower guide plate 201, the length of the second lower guide plate 202, or the length of the third lower guide plate 203. In one particular embodiment, the fourth lower guide plate 204 has a smallest length. In this way, the probe card structure 1 of the present disclosure can be used in a case where the objects to be tested (i.e., the first object to be tested T1, the second object to be tested T2, and the object to be tested T3) on the substrate S have three heights. The embodiments of the present disclosure are not intended to limit a relationship between the lengths of the lower guide plates, as long as the lengths of the contact ends of the plurality of first probes 30a, 30b, 30c, the plurality of second probes 40a, 40b, 40c, and the plurality of third probes 60a, 60b, 60c projecting from the lower guide plate 20 can be adjusted, the lengths of the lower guide plates can be combined by adopting those disclosed in the embodiments of the present disclosure.

In one particular embodiment, a distance between the fourth lower guide plate 204 and the first upper guide plate 101 is greater than the distance between the second lower guide plate 202 and the first upper guide plate 101. In addition, the length of the fourth lower guide plate 204 is less than the length of the first lower guide plate 201, and each of the first probe set 30 and the second probe set 40 does not pass through the fourth lower guide plate 204. In one particular embodiment, the thickness of the first lower guide plate 201 may be different from a thickness of the fourth lower guide plate 204.

Specifically, the fourth lower guide plate 204 is arranged below the third lower guide plate 203, and the stiffener 50 can be disposed between the third lower guide plate 203 and the fourth lower guide plate 204. In the present embodiment, the fourth lower guide plate 204 is arranged between the third lower guide plate 203 and an object to be tested T3, and generally arranged close an outside of the probe card structure 1. The plurality of third probes 60a, 60b, 60c passing through the fourth lower guide plate 204 correspond to the third object to be tested T3 having the lowest height, so that the lengths of the sixth contact ends 62 of the plurality of third probes 60a, 60b, 60c which have the longest lengths projecting from the fourth lower guide plate 204 can be determined through the fourth lower guide plate 204. However, in another embodiment of the present disclosure, the stiffener 50 may be not disposed between the third lower guide plate 203 and the fourth lower guide plate 204, and the lengths of the sixth contact ends 62 of the plurality of third probes 60a, 60b, 60c projecting from the fourth lower guide plate 204 through the fourth lower guide plate 204 having the thicker thickness.

### Seventh Embodiment

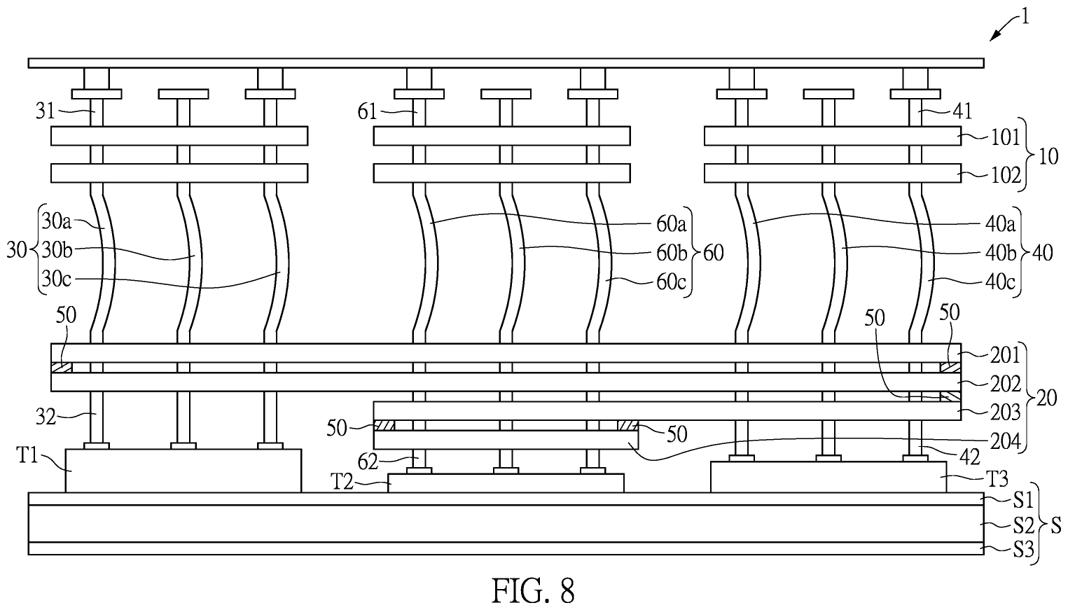

Referring to FIG. 8, which a seven embodiment of the present disclosure is shown, the present embodiment is substantially the same as the sixth embodiment, and the main difference is described as follows. In a probe card structure of the seventh embodiment of the present disclosure, the probe card structure is configured to detect the second object to be tested T2, which has a lower height, located between the first object to be tested T1 and the third object to be tested T3, which are relatively higher, on the substrate S. The fourth lower guide plate 204 is arranged corresponding to the second object to be tested T2, and the fourth lower guide plate 204 has the smallest size, i.e., when viewed form the side of the probe card structure 1, the fourth lower guide plate 204 has the smallest length. In the present embodiment, the fourth lower guide plate 204 is arranged between the third lower guide plate 203 and the object to be tested T2, and generally arranged close to an inside of the probe card structure 1.

That is, the fourth lower guide plate 204 can be arranged corresponding to the second object to be tested T2 having the lowest height to provide the third probes 60a, 60b, 60c which have longer lengths corresponding to the second object to be tested T2 having the lowest height, so that the distance between the second lower guide plate 202 and the first object to be tested T1 is substantially equal to the distance between the fourth lower guide plate 204 and the second object to be tested T2 or the distance between the third lower guide plate 203 and the third object to be tested T3. In this way, the probe card structure 1 of the present disclosure can be used to test various substrates S provided with the objects to be tested T having different heights.

In one particular embodiment of the present disclosure, the stiffener 50 can be disposed between the third lower guide plate 203 and the fourth lower guide plate 204, and arranged at one end of the fourth lower guide plate 204. However, in another embodiment of the present disclosure, the stiffener 50 can be disposed between the third lower guide plate 203 and the fourth lower guide plate 204, and arranged at two ends of the fourth lower guide plate 204 to more securely fix the third lower guide plate 203 and the fourth lower guide plate 204. Therefore, as long as any two of the lower guide plates can be fixed and kept at a longitudinal distance apart, a quantity and a position of the stiffener 50 are not particularly limited.

### Beneficial Effects of the Embodiments

In conclusion, in the probe card structure and the method of manufacturing the same provided by the present disclosure, by virtue of “the upper guide plate set including at least the first upper guide plate, and the first upper guide plate having the plurality of upper guide plate holes; the lower guide plate set being arranged parallel to the upper guide plate set and including at least the first lower guide plate and the second lower guide plate, each of the first lower guide plate and the second lower guide plate having the plurality of lower guide plate holes,” “the first probe set including the plurality of first probes, each of the plurality of first probes having the first contact end and the second contact end, the first contact ends correspondingly passing through the plurality of upper guide plate holes, and the second contact ends correspondingly passing through the plurality of lower guide plate holes; the second probe set including the plurality of second probes which have different lengths from those of the plurality of first probes, each of the plurality of second probes having the third contact end and the fourth contact end, the third contact ends correspondingly passing through the plurality of upper guide plate holes, and the fourth contact ends correspondingly passing through the plurality of lower guide plate holes; the length of each of the plurality of second probes being greater than the length of each of the plurality of first probes,” “the least one stiffener being disposed between the first lower guide plate and the second lower guide plate,” “the plurality of first probes and the plurality of second probes correspondingly passing through the first upper guide plate, and the plurality of first probes and the plurality of second probes correspondingly passing through at least one of the first lower guide plate and the second lower guide plate,” “the position of the first lower guide plate determining the lengths of the second contact ends projecting from the lower guide plate set, and the position of the second lower guide plate determining the lengths of the fourth contact ends projecting from the lower guide plate set,” and “the first contact ends and the third contact ends being coplanar, and the second contact ends and the fourth contact ends being not coplanar,” the probes can be in uniform contact with corresponding pads or bumps on the objects to be tested, so that a test capability of the probe card can be improved.

Further, the third lower guide plate and/or the fourth guide plate of the present disclosure can be arranged corresponding to the object to be tested having the lowest height, to provide the probes having longer lengths corresponding to the object to be tested having the lowest height. Accordingly, when the probe card structure of the present disclosure is used to test the objects to be tested having different heights on the same substrate, the tips of the probes have the very similar balance contact force, thereby improving the test capability of the probe card.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A probe card structure, comprising:
an upper guide plate set including at least a first upper guide plate, wherein the first upper guide plate has a plurality of upper guide plate holes;
a lower guide plate set arranged parallel to the upper guide plate set and including a first lower guide plate and a second lower guide plate, wherein each of the first lower guide plate and the second lower guide plate has a plurality of lower guide plate holes;
a first probe set including a plurality of first probes, wherein each of the plurality of first probes has a first contact end and a second contact end, the first contact ends correspondingly pass through the plurality of upper guide plate holes, and the second contact ends correspondingly pass through the plurality of lower guide plate holes;
a second probe set including a plurality of second probes, wherein each of the plurality of second probes has a third contact end and a fourth contact end, the third contact ends correspondingly pass through the plurality of upper guide plate holes, and the fourth contact ends correspondingly pass through the plurality of lower guide plate holes; wherein a length of each of the plurality of second probes is greater than a length of each of the plurality of first probes; and
at least one stiffener disposed between the first lower guide plate and the second lower guide plate;
wherein both of the plurality of first probes and the plurality of second probes correspondingly pass through the first upper guide plate, and both of the plurality of first probes and the plurality of second probes correspondingly pass through at least one of the first lower guide plate and the second lower guide plate;
wherein a position of the first lower guide plate determines lengths of the second contact ends projecting from the lower guide plate set, and a position of the second lower guide plate determines lengths of the fourth contact ends projecting from the lower guide plate set;
wherein the first contact ends and the third contact ends are coplanar, and the second contact ends and the fourth contact ends are not coplanar.

2. The probe card structure according to claim 1, wherein a distance between the second lower guide plate and the first upper guide plate is greater than a distance between the first lower guide plate and the first upper guide plate; wherein a length of the second lower guide plate is less than a length of the first lower guide plate.

3. The probe card structure according to claim 2, wherein the first probe set passes through the first lower guide plate, and the second probe set correspondingly passes through the first lower guide plate and the second lower guide plate.

4. The probe card structure according to claim 1, wherein the upper guide plate set further includes a second upper guide plate, the second upper guide plate is arranged parallel to the first upper guide plate, and the second upper guide plate has the plurality of upper guide plate holes corresponding to the plurality of upper guide plate holes of the first upper guide plate.

5. The probe card structure according to claim 1, wherein the first upper guide plate further has a first section and a second section that are separated from each other; wherein the first probe set passes through the first section, and the second probe set passes through the second section.

6. The probe card structure according to claim 1, wherein the first lower guide plate further has a third section and a fourth section that are separated from each other; wherein the first probe set passes through the third section, and the second probe set passes through the fourth section.

7. The probe card structure according to claim 2, wherein the lower guide plate set further includes a third lower guide plate, and the third lower guide plate has the plurality of lower guide plate holes; wherein a distance between the third lower guide plate and the first upper guide plate is less than the distance between the first lower guide plate and the first upper guide plate.

8. The probe card structure according to claim 7, wherein the first probe set correspondingly passes through the plurality of lower guide plate holes of the first lower guide plate and the plurality of lower guide plate holes of the third lower guide plate, and the second probe set correspondingly passes through the plurality of lower guide plate holes of the first lower guide plate, the plurality of lower guide plate holes of the second lower guide plate, and the plurality of lower guide plate holes of the third lower guide plate.

9. The probe card structure according to claim 7, wherein the first probe set correspondingly passes through the plurality of lower guide plate holes of the first lower guide plate and the plurality of lower guide plate holes of the third lower guide plate, and the second probe set correspondingly passes through the plurality of lower guide plate holes of the first lower guide plate and the plurality of lower guide plate holes of the second lower guide plate; wherein a length of the third lower guide plate is less than the length of the first lower guide plate.

10. The probe card structure according to claim 8, wherein the first lower guide plate and the second lower guide plate have different thicknesses.

11. The probe card structure according to claim 1, wherein the first probe set and the second probe set each are vertical probes.

12. The probe card structure according to claim 1, wherein the first probe set and the second probe set have different tip thicknesses.

13. The probe card structure according to claim 1, further comprising:
a third probe set including a plurality of third probes;
wherein each of the plurality of third probes has a fifth contact end and a sixth contact end; wherein the lower guide plate set includes a fourth lower guide plate, and the fourth lower guide plate has the plurality of lower guide plate holes; wherein the fifth contact ends correspondingly pass through the plurality of upper guide plate holes, the sixth contact ends correspondingly pass through the plurality of lower guide plate holes, and a length of each of the plurality of third probes is greater than the length of each of the plurality of second probes; wherein a position of the fourth lower guide plate determines lengths of the sixth contact ends projecting form the lower guide plate set; wherein the first contact ends, the third contact ends, and the fifth contact ends are coplanar, and the second contact ends, the fourth contact ends, and the sixth contact ends are not coplanar.

14. The probe card structure according to claim 13, wherein a distance between the fourth lower guide plate and the first upper guide plate is greater than the distance between the second guide plate and the first upper guide plate.

15. The probe card structure according to claim 14, wherein a distance between the second lower guide plate and the first upper guide plate is greater than a distance between the first lower guide plate and the first upper guide plate; wherein a length of the second lower guide plate is less than a length of the first lower guide plate.

16. The probe card structure according to claim 15, wherein the lower guide plate set further includes a third lower guide plate, and the third lower guide plate has the plurality of lower guide plate holes; wherein a distance between the third lower guide plate and the first upper guide plate is less than the distance between the first lower guide plate and the first upper guide plate.

17. The probe card structure according to claim 16, wherein the first probe set correspondingly passes through the plurality of lower guide plate holes of the first lower guide plate and the plurality of lower guide plate holes of the third lower guide plate, and the second probe set correspondingly passes through the plurality of lower guide plate holes of the first lower guide plate, the plurality of lower guide plate holes of the second lower guide plate, and the plurality of lower guide plate holes of the third lower guide plate.

18. The probe card structure according to claim 13, wherein each of the first probe set and the second set does not pass through the fourth lower guide plate.

19. The probe card structure according to claim 13, wherein a length of the fourth lower guide plate is less than the length of the first lower guide plate.

20. The probe card structure according to claim 13, wherein the first lower guide plate and the fourth lower guide plate have different thicknesses.

21. The probe card structure according to claim 2, wherein the first lower guide plate and the second lower guide plate have different thicknesses.
